(19) United States
(12) Patent Application Publication
(10) Pub. No.: US 2024/0420923 A1
(43) Pub. Date: Dec. 19, 2024

(54) PLASMA PROCESSING APPARATUS

(71) Applicant: Tokyo Electron Limited, Tokyo (JP)

(72) Inventors: Manabu ISHIKAWA, Miyagi (JP); Takumi IMAHASHI, Miyagi (JP); Hiroki SATO, Miyagi (JP)

(73) Assignee: Tokyo Electron Limited, Tokyo (JP)

(21) Appl. No.: 18/741,841

(22) Filed: Jun. 13, 2024

(30) Foreign Application Priority Data
Jun. 13, 2023 (JP) 2023-096776
Jun. 4, 2024 (JP) 2024-090672

(51) Int. Cl. H01J 37/32

(52) U.S. Cl. CPC H01J 37/32183; H01J 37/32568; H01J 37/32642; H01J 2237/24564

(57) ABSTRACT

A plasma processing apparatus includes a chamber, a bias power supply, a substrate support configured to support a substrate and an edge ring in the chamber, a plurality of first impedance adjusting mechanisms, and an electrical path. The substrate support includes a first region configured to support the substrate, a second region provided around the first region and configured to support the edge ring, a first bias electrode provided in the first region, a plurality of first impedance adjusting electrodes provided in the first region and grounded, and a second bias electrode provided in the second region. The plurality of first impedance adjusting mechanisms are configured to be respectively connected to the plurality of first impedance adjusting electrodes. The electrical path is configured to connect the bias power supply, the first bias electrode, and the second bias electrode.

### CROSS-REFERENCE TO RELATED APPLICATIONS

The present application claims priority to and incorporates by reference the entire contents of Japanese Patent Application No. 2023-096776 filed in Japan on Jun. 13, 2023 and Japanese Patent Application No. 2024-090672 filed in Japan on Jun. 4, 2024.

### FIELD

Exemplary embodiments disclosed herein relate to a plasma processing apparatus.

### BACKGROUND

Japanese Laid-open Patent Publication No. 2017-130659 discloses that as the plasma sheath drops adjacent the edge ring due to edge ring erosion, the capacitance of the variable capacitor is adjusted in order to affect the RF amplitude near the edge of the substrate.

According to an aspect of embodiments, a plasma processing apparatus that can suppress unevenness in etching rate is provided.

### SUMMARY

According to an aspect of a present disclosure, a plasma processing apparatus includes: a chamber; a bias power supply; a substrate support configured to support a substrate and an edge ring in the chamber; a plurality of first impedance adjusting mechanisms; and an electrical path, the substrate support including a first region configured to support the substrate, a second region provided around the first region and configured to support the edge ring, a first bias electrode provided in the first region, a plurality of first impedance adjusting electrodes provided in the first region and grounded, and a second bias electrode provided in the second region, wherein the plurality of first impedance adjusting mechanisms are configured to be respectively connected to the plurality of first impedance adjusting electrodes, and the electrical path is configured to connect the bias power supply, the first bias electrode, and the second bias electrode.

### BRIEF DESCRIPTION OF DRAWINGS

FIG. 1 is a diagram illustrating an example of a plasma processing apparatus according to a first embodiment of the present disclosure;

FIG. 2 is a diagram illustrating an example of a configuration of electrodes according to the first embodiment;

FIG. 3 is a diagram illustrating an example of an equivalent circuit of an electrostatic chuck and plasma according to the first embodiment;

FIG. 4 is a diagram illustrating an example of a circuit configuration of an impedance adjusting mechanism according to the first embodiment;

FIG. 5 is a diagram illustrating an example of unevenness in etching rate;

FIG. 6 is a diagram illustrating an example of change in etching rate when the impedance adjusting mechanism on the annular region side is changed;

FIG. 7 is a diagram illustrating an example of change in etching rate when the impedance adjusting mechanism on the annular region side is changed;

FIG. 8 is a diagram illustrating an example of the rate of change in etching rate when the impedance adjusting mechanism on the annular region side is changed;

FIG. 9 is a diagram illustrating an example of impedance adjusting electrodes according to the first embodiment;

FIG. 10 is a diagram illustrating an example of experimental results of tilt control;

FIG. 11 is a diagram illustrating an example of impedance adjusting electrodes in a first alternative example;

FIG. 12 is a diagram illustrating an example of a configuration of an electrical path according to a second embodiment;

FIG. 13 is a diagram illustrating an example of change in etching rate when feedback control of bias RF power is not performed;

FIG. 14 is a diagram illustrating an example of change in etching rate and in potential of a substrate when feedback control of bias RF power is not performed;

FIG. 15 is a diagram illustrating an example of change in etching rate when feedback control of bias RF power is not performed;

FIG. 16 is a diagram illustrating an example of change in etching rate and in potential of a substrate when feedback control of bias RF power is not performed;

FIG. 17 is a diagram illustrating an example of change in etching rate when feedback control of bias RF power is performed;

FIG. 18 is a diagram illustrating an example of change in etching rate and in potential of a pedestal when feedback control of bias RF power is performed;

FIG. 19 is a diagram illustrating an example of change in etching rate when feedback control of bias RF power is performed;

FIG. 20 is a diagram illustrating an example of change in etching rate and in potential of a pedestal when feedback control of bias RF power is performed;

FIG. 21 is a diagram illustrating an example of change in current when feedback control of bias DC power is not performed;

FIG. 22 is a diagram illustrating an example of change in etching rate when feedback control of bias DC power is not performed; and

FIG. 23 is a diagram illustrating an example of change in etching rate when feedback control of bias DC power is performed.

### DESCRIPTION OF EMBODIMENTS

Exemplary embodiments of a plasma processing apparatus disclosed here will be described in detail below based on the drawings. The disclosed technology is not limited by the following exemplary embodiments.

In a plasma processing apparatus, a plasma sheath may vary in thickness with the potential difference between a substrate and an edge ring. Thus, the direction of an electric field may not be perpendicular to the substrate, and the trajectories of ions may be inclined, causing tilting in which an etching hole is obliquely inclined. The tilting is caused not only by the potential difference between the substrate and the edge ring. Global tilting is also a problem, in which the position dependency of the plasma sheath appears in a radial or circumferential direction over the entire substrate due to a potential difference caused by subtle variations in thickness of electrodes in a substrate support and a ceramic plate. In this respect, for example, the potential may be controlled independently on the substrate side and the edge ring side. However, the arrangement of an impedance adjusting mechanism for controlling the potential and the arrangement of a conductive portion for extracting the impedance adjusting electrode to the outside of the substrate support may cause unevenness in etching rate. When the etching rate in an outer peripheral portion of the substrate is controlled, the etching rate of an inner peripheral portion of the substrate may also change simultaneously. It is therefore expected to improve the controllability of etching rate and suppress unevenness in etching rate.

### First Embodiment

### Configuration of Plasma Processing Apparatus 1

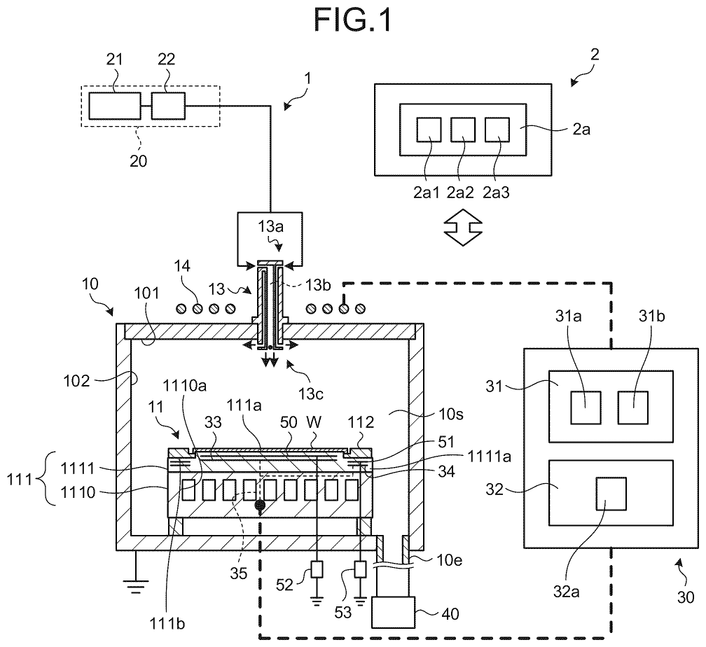

An example configuration of a plasma processing system will be described below. FIG. 1 is a diagram illustrating an example of a plasma processing apparatus according to a first embodiment of the present disclosure. The plasma processing system includes an inductively coupled plasma processing apparatus 1 and a controller 2. The inductively coupled plasma processing apparatus 1 includes a plasma processing chamber 10, a gas supply unit 20, a power supply 30, and an exhaust system 40. The plasma processing chamber 10 includes a dielectric window 101. The plasma processing apparatus 1 also includes a substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s defined by the dielectric window 101, a side wall 102 of the plasma processing chamber 10, and the substrate support 11. The plasma processing chamber 10 has at least one gas supply port for supplying at least one processing gas to the plasma processing space 10s and at least one gas discharge port for discharging the gas from the plasma processing space. The plasma processing chamber 10 is grounded.

The substrate support 11 includes a body 111 and a ring assembly 112. The body 111 has a central region 111a for supporting a substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 so as to surround the substrate W on the central region 111a of the body 111. Thus, the central region 111a is also referred to as substrate support surface for supporting the substrate W, and the annular region 111b is also referred to as ring support surface for supporting the ring assembly 112. The substrate support 11 is an example of a substrate support, the central region 111a is an example of a first region, and the annular region 111b is an example of a second region. In the following description, the central region 111a may be represented as substrate support surface 111a, and the annular region 111b may be represented as ring support surface 111b.

In one embodiment, the body 111 includes a pedestal 1110 and an electrostatic chuck 1111. The pedestal 1110 includes a conductive member. The conductive member of the pedestal 1110 can function as a part of an electrical path 35 that is connected to a first bias electrode 33 and a second bias electrode 34 described below. The electrostatic chuck 1111 is disposed on the pedestal 1110. The electrostatic chuck 1111 includes a ceramic member 1111a and a not-illustrated electrostatic electrode disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Furthermore, at least one RF/DC electrode coupled to a radio frequency (RF) power supply 31 and/or a direct current (DC) power supply 32, which will be described below, may be disposed in the ceramic member 1111a. In this case, at least one RF/DC electrode functions as a bias electrode. In other words, the first bias electrode 33 and the second bias electrode 34 described below are electrically connected to the RF power supply 31 and/or the DC power supply 32 through the electrical path 35. The conductive member of the pedestal 1110 and at least one RF/DC electrode may function as a plurality of bias electrodes. The not-illustrated electrostatic electrode may function as a bias electrode, or the first bias electrode 33 may function as an electrostatic electrode. Thus, the substrate support 11 includes at least one bias electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

The substrate support 11 may include a temperature adjusting module configured to adjust at least one of the electrostatic chuck 1111, the ring assembly 112, and the substrate W to a target temperature. The temperature adjusting module may include a heater, a heat transfer medium, a flow path 1110a, or a combination thereof. A heat transfer fluid such as brine or gas flows through the flow path 1110a. In one embodiment, the flow path 1110a is formed in the pedestal 1110, and one or more heaters are disposed in the ceramic member 1111a of the electrostatic chuck 1111. The substrate support 11 may include a heat transfer gas supply unit configured to supply a heat transfer gas to a gap between the reverse face of the substrate W and the central region 111a.

The electrostatic chuck 1111 includes a first impedance adjusting electrode 50 and a first bias electrode 33 inside in order from the substrate support surface 111a in a lower portion of the substrate support surface 111a, and is formed of a dielectric such as ceramic. Furthermore, the electrostatic chuck 1111 includes a second impedance adjusting electrode 51 and a second bias electrode 34 inside in order from the ring support surface 111b in a lower portion of the ring support surface 111b. The first bias electrode 33 and the second bias electrode 34 are connected to the pedestal 1110 by conductive members to form the electrical path 35. The connection of the first bias electrode 33 and the second bias electrode 34 to the pedestal 1110 is not limited to conductive members, but can employ any technique that can supply bias RF signals, such as magnetic resonance, capacitive coupling, and inductive coupling. In other words, the electrical path 35 is configured to connect a bias power supply (for example, a second RF generator 31b described below), the first bias electrode 33, and the second bias electrode 34. Furthermore, the electrical path 35 may be such that the second RF generator 31b described below is not connected to the pedestal 1110 but the second RF generator 31b is directly connected to the first bias electrode 33 and the second bias electrode 34.

The first impedance adjusting electrode 50 is grounded through an impedance adjusting mechanism 52. The impedance adjusting mechanism 52 adjusts the amount to flow to the ground (earth) for a part of RF signal (electrical bias) supplied from the first bias electrode 33. By adjusting the amount of RF signal to flow to the ground by the first impedance adjusting electrode 50, the potential of the substrate W is adjusted to be used for control of the tilt angle and/or adjustment of the etching rate. The first impedance adjusting electrode 50 is provided in the electrostatic chuck 1111. The impedance adjusting mechanism 52 is connected to the first impedance adjusting electrode 50. When a plurality of first impedance adjusting electrodes 50 are provided, for example, two or more are provided in the circumferential direction of the substrate support 11, and a corresponding number of impedance adjusting mechanisms 52 corresponding to the first impedance adjusting electrodes 50 are provided. Two or more first impedance adjusting electrodes 50 may be provided in the radial direction of the substrate support 11. Furthermore, two or more first impedance adjusting electrodes 50 may be provided in each of the circumferential direction and the radial direction of the substrate support 11. The first impedance adjusting electrode 50 is disposed parallel to the first bias electrode 33.

The second impedance adjusting electrode 51 is grounded through an impedance adjusting mechanism 53. The impedance adjusting mechanism 53 adjusts the amount to flow to the ground (earth) for a part of RF signal (electrical bias) supplied from the second bias electrode 34. By adjusting the amount of RF signal to flow to the ground by the second impedance adjusting electrode 51, the potential of the ring assembly 112 is adjusted to be used for control of the tilt angle and/or adjustment of the etching rate. The second impedance adjusting electrode 51 is provided in the electrostatic chuck 1111. When a plurality of second impedance adjusting electrodes 51 are provided, for example, two or more are provided in the circumferential direction of the substrate support 11, and a corresponding number of impedance adjusting mechanisms 53 corresponding to the second impedance adjusting electrodes 51 are provided. Two or more second impedance adjusting electrodes 51 may be provided in the radial direction of the substrate support 11. Furthermore, two or more second impedance adjusting electrodes 51 may be provided in each of the circumferential direction and the radial direction of the substrate support 11. The second impedance adjusting electrode 51 is disposed parallel to the second bias electrode 34.

The first bias electrode 33 and the second bias electrode 34 are brought as close as possible to the substrate W and the ring assembly 112 to reduce the impedance of capacitors constituted with the substrate W and the ring assembly 112, the ceramic of the electrostatic chuck 1111, and the electrodes. Thus, the respective potential differences between the first bias electrode 33 and the second bias electrode 34, and the substrate W and the ring assembly 112 are reduced. Similarly, the impedance of respective capacitors constituted with the first bias electrode 33 and the second bias electrode 34, and the first impedance adjusting electrode 50 and the second impedance adjusting electrode 51 is reduced. Furthermore, the impedance of capacitors constituted with the first impedance adjusting electrode 50 and the second impedance adjusting electrode 51, and the substrate W and the ring assembly 112 is also reduced.

At least one of the impedance adjusting mechanisms 52 and 53 may be provided, or both may be provided. When one of the impedance adjusting mechanisms 52 and 53 is not prepared, the first impedance adjusting electrode 50 or the second impedance adjusting electrode 51 that is not provided with the impedance adjusting mechanism is connected to the earth (ground) through a predetermined impedance, or is not connected to the earth and is in a floating state. When one of the impedance adjusting mechanisms 52 and 53 is not prepared, the first impedance adjusting electrode 50 or the second impedance adjusting electrode 51 that is not provided with the impedance adjusting mechanism need not be prepared.

The gas introduction unit is configured to introduce at least one processing gas from the gas supply unit 20 into the plasma processing space 10s. In one embodiment, the gas introduction unit includes a center gas injector (CGI) 13. The center gas injector 13 is disposed above the substrate support 11 and is attached to a central opening formed in the dielectric window 101. The center gas injector 13 has at least one gas supply port 13a, at least one gas flow path 13b, and at least one gas introduction port 13c. The processing gas supplied to the gas supply port 13a passes through the gas flow path 13b and is introduced into the plasma processing space 10s through the gas introduction port 13c. In addition to or instead of the center gas injector 13, the gas introduction unit may include one or more side gas injectors (SGI) that are attached to one or more openings formed in the side wall 102.

The gas supply unit 20 may include at least one gas source 21 and at least one flow controller 22. In one embodiment, the gas supply unit 20 is configured to supply at least one processing gas from respective corresponding gas sources 21 to the gas introduction unit through respective corresponding flow controllers 22. Each of the flow controllers 22 may include, for example, a mass flow controller or a pressure-controlled flow controller. In addition, the gas supply unit 20 may include one or more flow modulation devices that modulate or pulse the flow volume of at least one processing gas.

The power supply 30 includes the RF power supply 31 coupled to the plasma processing chamber 10 through at least one impedance matching circuit. The RF power supply 31 is configured to supply at least one RF signal (RF power) to at least one first bias electrode 33 and second bias electrode 34, and the antenna 14. Thus, plasma is formed from at least one processing gas supplied to the plasma processing space 10s. Accordingly, the RF power supply 31 can function as at least a part of a plasma generator configured to generate plasma from one or more processing gases in the plasma processing chamber 10. Furthermore, a bias RF signal is supplied to at least one first bias electrode 33 and second bias electrode 34 to generate a bias potential in the substrate W, so that ions in the formed plasma can be drawn into the substrate W.

In one embodiment, the RF power supply 31 includes a first RF generator 31a and a second RF generator 31b. The first RF generator 31a is coupled to the antenna 14 and configured to generate a source RF signal (source RF power) for plasma generation through at least one impedance matching circuit. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to the antenna 14.

The second RF generator 31b is coupled to at least one first bias electrode 33 and second bias electrode 34 through at least one impedance matching circuit and configured to generate a bias RF signal (bias RF power). The frequency of the bias RF signal may be the same as or different from the frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one first bias electrode 33 and second bias electrode 34. In various exemplary embodiments, at least one of the source RF signal and the bias RF signal may be pulsed.

Furthermore, the power supply 30 may include the DC power supply 32 coupled to the plasma processing chamber 10. The DC power supply 32 includes a bias DC generator 32a. In one embodiment, the bias DC generator 32a is connected to at least one first bias electrode 33 and second bias electrode 34 and configured to generate a bias DC signal. The generated bias DC signal is applied to at least one first bias electrode 33 and second bias electrode 34.

In various exemplary embodiments, the bias DC signal may be pulsed. In this case, a sequence of voltage pulses is applied to at least one first bias electrode 33 and second bias electrode 34. The voltage pulse may have a pulse waveform such as rectangle, trapezoid, triangle, or a combination thereof. In one embodiment, a waveform generator for generating a sequence of voltage pulses from a DC signal is connected between the bias DC generator 32a and at least one bias electrode. Accordingly, the bias DC generator 32a and the waveform generator constitute a voltage pulse generator. The voltage pulse may have a positive polarity or a negative polarity. Furthermore, the sequence of voltage pulses may include one or more positive voltage pulses and one or more negative voltage pulses in one cycle. The bias DC generator 32a may be provided in addition to the RF power supply 31 or instead of the second RF generator 31b.

The antenna 14 includes one or more coils. In one embodiment, the antenna 14 may include an outer coil and an inner coil disposed coaxially. In this case, the RF power supply 31 may be connected to both the outer coil and the inner coil or may be connected to one of the outer coil and the inner coil. In the former case, the same RF generator may be connected to both the outer coil and the inner coil, or separate RF generators may be respectively connected to the outer coil and the inner coil.

The exhaust system 40 may be connected, for example, to a gas discharge port 10e provided at the bottom of the plasma processing chamber 10. The exhaust system 40 may include a pressure regulating valve and a vacuum pump. The pressure in the plasma processing space 10s is regulated by the pressure regulating valve. The vacuum pump may include a turbomolecular pump, a dry pump, or a combination thereof.

The controller 2 processes computer-executable instructions that cause the plasma processing apparatus 1 to perform various processes described in the present disclosure. The controller 2 can be configured to control each element of the plasma processing apparatus 1 to perform various processes described herein. In one embodiment, a part or all of the controller 2 may be included in the plasma processing apparatus 1. The controller 2 may include a processing unit 2al, a storage 2a2, and a communication interface 2a3. The controller 2 is implemented, for example, by a computer 2a. The processing unit 2al can be configured to perform various control operations by reading a computer program from the storage 2a2 and executing the read computer program. The computer program may be stored in the storage 2a2 in advance or may be obtained via a medium when needed. The obtained computer program is stored into the storage 2a2 and read from the storage 2a2 by the processing unit 2al for execution. The medium may be various storage media readable by the computer 2a or a communication line connected to the communication interface 2a3. The processing unit 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Potential on Substrate Support 11

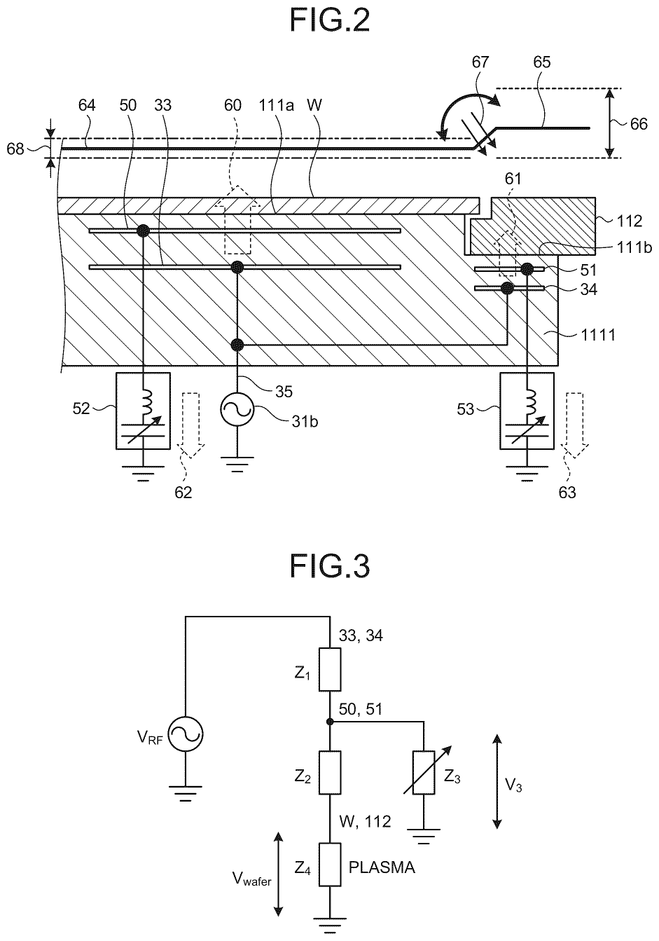

Referring now to FIG. 2, the potential on the substrate support 11 will be described. FIG. 2 is a diagram illustrating an example of a configuration of electrodes according to the first embodiment. In FIG. 2, the first bias electrode 33 and the second bias electrode 34 are supplied with bias RF signals from the second RF generator 31b through the electrical path 35 of the pedestal 1110 and conductive members.

As illustrated in FIG. 2, at the substrate support surface 111a, a bias RF signal supplied from the first bias electrode 33 disposed in the lower portion thereof is divided into an RF signal 60 and an RF signal 62. The RF signal 60 is an RF signal that is supplied to plasma through the first impedance adjusting electrode 50 and the substrate W. The RF signal 62 is an RF signal that flows from the first impedance adjusting electrode 50 to the ground (earth) through the impedance adjusting mechanism 52. Furthermore, at the ring support surface 111b, a bias RF signal supplied from the second bias electrode 34 disposed in the lower portion thereof is divided into an RF signal 61 and an RF signal 63. The RF signal 61 is an RF signal that is supplied to plasma through the second impedance adjusting electrode 51 and the ring assembly 112. The RF signal 63 is an RF signal that flows from the second impedance adjusting electrode 51 to the ground (earth) through the impedance adjusting mechanism 53.

At this time, it is assumed that a potential 64, which is a line that images a predetermined potential in an upper portion of the substrate W, and a potential 65, which is a line that images a predetermined potential in an upper portion of the ring assembly 112, are at different heights, for example, as illustrated in FIG. 2. In this case, the height of the potential 65 is adjusted within a range 66, for example, by adjusting the impedance adjusting mechanism 53. Thus, in the first embodiment, the tilt angle corresponding to a direction 67 of an electric field can be controlled by the ratio between the potential 64 and the potential 65. Furthermore, the etching rate in the outer peripheral portion of the substrate W and the etching rate in the inner peripheral portion of the substrate W are controlled, for example, by adjusting the impedance adjusting mechanism 52 and the impedance adjusting mechanism 53. When the impedance adjusting mechanism 52 is adjusted, the height of the potential 64 is adjusted within a range 68. Thus, in the first embodiment, it is possible to suppress simultaneous change of the etching rate in the inner peripheral portion of the substrate W when the etching rate in the outer peripheral portion of the substrate W is controlled. In FIG. 2, the angle of the direction 67 of the electric field is emphasized for sake of illustration. In the first embodiment, the first impedance adjusting electrode 50 and the second impedance adjusting electrode 51 are embedded in the electrostatic chuck 1111, so the structure of the plasma processing apparatus 1 can be made compact.

Referring now to FIG. 3, an equivalent circuit of a circuit through which a bias RF signal flows will be described. FIG. 3 is a diagram illustrating an example of an equivalent circuit of an electrostatic chuck and plasma according to the first embodiment. In FIG. 3, bias RF signals supplied to the first bias electrode 33 and the second bias electrode 34 are represented by V_{RF}. Furthermore, the impedance between the first bias electrode 33 and the second bias electrode 34, and the first impedance adjusting electrode 50 and the second impedance adjusting electrode 51 is represented by Z₁. Furthermore, the impedance between the first impedance adjusting electrode 50 and the second impedance adjusting electrode 51, and the substrate W and the ring assembly 112 is represented by Z₂. Furthermore, the impedance of the impedance adjusting mechanisms 52 and 53 between the first impedance adjusting electrode 50 and the second impedance adjusting electrode 51, and the ground (earth) is represented by Z₃. Furthermore, the impedance of plasma between the substrate W and the ring assembly 112, and the ground is represented by Z₄.

Here, a voltage V₃ applied to Z₃ and a voltage V_{wafer} applied to Z₄ can be represented by the following Equations (1) and (2), respectively. In Equations (1) to (4), V_{RF} is represented by V.

$${V}_{3} = \frac{{Z}_{3}}{{Z}_{1} + {Z}_{3}} V \qquad ( 1 )$$

$${V}_{wafer} = \frac{{Z}_{4}}{{Z}_{2} + {Z}_{4}} {V}_{3} \qquad ( 2 )$$

By substituting Equation (1) into Equation (2), the voltage V_{wafer} applied to Z₄ can be represented by the following Equation (3). Dividing the fractional terms in Equation (3) respectively by Z₄ and Z₃ yields the following Equation (4).

$${V}_{wafer} = \frac{{Z}_{4}}{{Z}_{2} + {Z}_{4}} \frac{{Z}_{3}}{{Z}_{1} + {Z}_{3}} V \qquad ( 3 )$$

$${V}_{wafer} = \frac{1}{\frac{{Z}_{2}}{{Z}_{4}} + 1} \frac{1}{\frac{{Z}_{1}}{{Z}_{3}} + 1} V \qquad ( 4 )$$

The fractional terms in Equation (4) are in the form of f(x)=1/(x+1), where f(x) is a function that approaches 1 as x decreases. Accordingly, according to Equation (4), the smaller Z₂ with respect to Z₄, the more efficient the transmission of potential to the plasma. The smaller Z₁ with respect to Z₃, the more efficient the transmission of potential to the plasma. To reduce Z₂, it is preferable to bring the first impedance adjusting electrode 50 and the second impedance adjusting electrode 51 as close as possible to the substrate W and the ring assembly 112, respectively. Similarly, to reduce Z₁, it is preferable to bring the first bias electrode 33 and the second bias electrode 34 as close as possible to the first impedance adjusting electrode 50 and the second impedance adjusting electrode 51, respectively. In this way, the sensitivity of potential control can be increased by bringing the first bias electrode 33 and the second bias electrode 34, the first impedance adjusting electrode 50 and the second impedance adjusting electrode 51, and the substrate W and the ring assembly 112 as close as possible.

Potential Control Based on Equivalent Circuit Based on the equivalent circuit illustrated in FIG. 3, the potential control in the plasma processing apparatus 1 controls Z₃ of the impedance adjusting mechanism 52 so that Z₃ between the first impedance adjusting electrode 50 and the ground is larger than Z₁ between the first bias electrode 33 and the first impedance adjusting electrode 50. In other words, the controller 2 of the plasma processing apparatus 1 controls the potential of the first impedance adjusting electrode 50 by controlling Z₃ of the impedance adjusting mechanism 52.

Furthermore, the potential control in the plasma processing apparatus 1 controls Z₃ of the impedance adjusting mechanism 53 so that Z₃ between the second impedance adjusting electrode 51 and the ground is larger than Z₁ between the second bias electrode 34 and the second impedance adjusting electrode 51. In other words, the controller 2 of the plasma processing apparatus 1 controls the potential of the second impedance adjusting electrode 51 by controlling Z₃ of the impedance adjusting mechanism 53.

### Circuit Configuration of Impedance Adjusting Mechanism

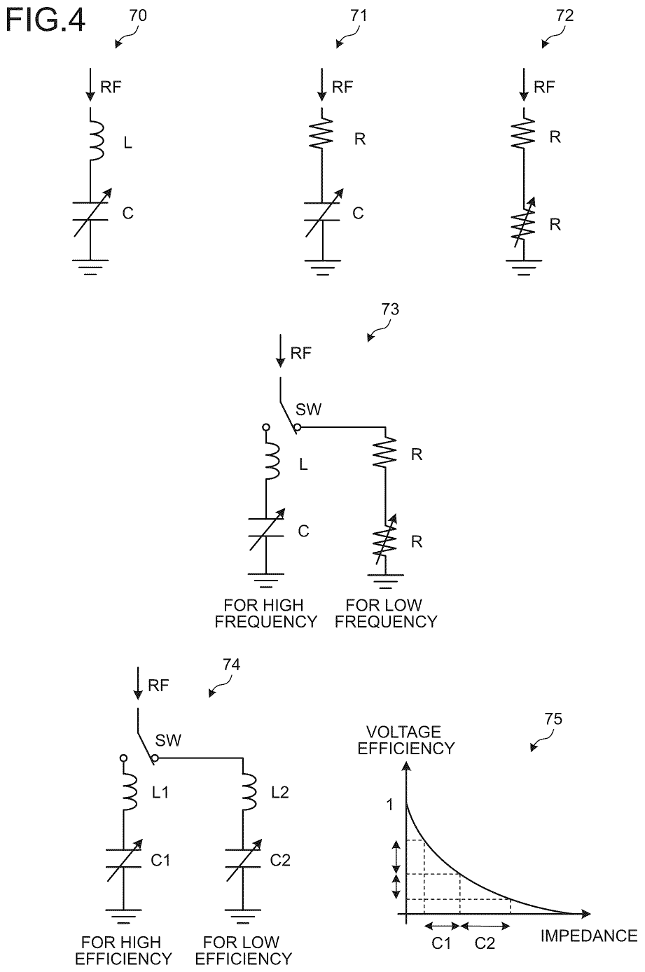

Referring now to FIG. 4, variations of the circuit configuration in the impedance adjusting mechanisms 52 and 53 will be described. FIG. 4 is a diagram illustrating an example of a circuit configuration of an impedance adjusting mechanism according to the first embodiment. As illustrated in FIG. 4, the impedance adjusting mechanisms 52 and 53 may have various configurations, such as circuits 70 to 74. The circuit 70 is an LC series circuit using an inductor and a variable capacitor. The circuit 71 is an RC series circuit using a resistor and a variable capacitor. The circuit 72 is an RR series circuit using a resistor and a variable resistor. The circuit 73 is a circuit in which an LC series circuit for high frequency and an RR series circuit for low frequency can be switched by a switch SW. The circuit 74 is a circuit in which an LC series circuit for high efficiency and an LC series circuit for low efficiency can be switched by a switch SW. The circuit 74 is configured to widen an adjustment range by switching the switch SW, as illustrated in Graph 75. Although not illustrated in FIG. 4, the impedance adjusting mechanisms 52 and 53 may have a circuit configuration using a variable inductor.

In this way, the impedance adjusting mechanisms 52 and 53 can use a variable resistor, a variable capacitor, a variable inductor, and the like, regardless of the type of circuit constants (R, L, C) to be adjusted. Furthermore, the impedance adjusting mechanisms 52 and 53 may combine one or more variable mechanisms (variable resistor, variable capacitor, variable inductor, and the like) according to the frequency of the bias RF signal, the size of a part, and the adjustment range. The impedance adjusting mechanisms 52 and 53 can use a variable resistor or a variable capacitor because it is not necessary to allow heater current to pass through. Furthermore, the impedance adjusting mechanisms 52 and 53 may be configured with at least one of a variable resistor, a variable capacitor, a variable inductor, and a DC power supply. For example, when the bias RF signal has high frequency, the above Z₁ and Z₂ are small values, so the potential can be controlled more effectively by controlling the potential using a DC power supply.

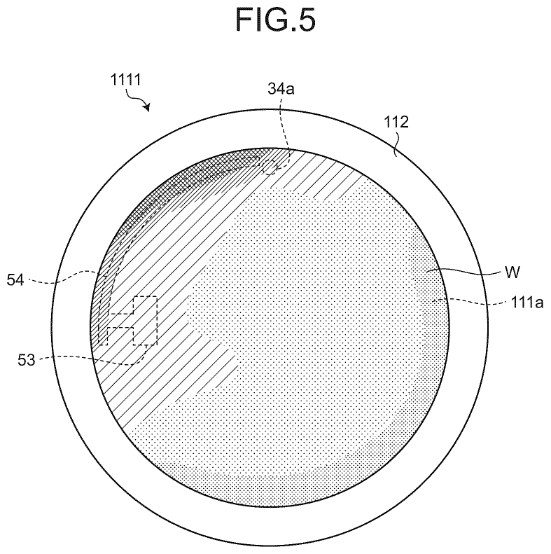

Unevenness in Etching Rate Referring now to FIG. 5 to FIG. 8, unevenness and change in etching rate will be described. FIG. 5 is a diagram illustrating an example of unevenness in etching rate. FIG. 5 illustrates unevenness in etching rate in the substrate W when adjustment by the impedance adjusting mechanisms 52 and 53 is not performed in the electrostatic chuck 1111 in a plan view. In FIG. 5, the difference in etching rate is represented by the difference in hatching. As illustrated in FIG. 5, an extraction electrode 34a connected to the second bias electrode 34, the impedance adjusting mechanism 53, and an arc-shaped conductive bar 54 connected to the impedance adjusting mechanism 53 are disposed in the lower portion of the substrate support surface 111a. The extraction electrode 34a constitutes a part of the electrical path 35 and is connected to the second RF generator 31b. Furthermore, the conductive bar 54 is disposed along the inner peripheral side of the ring assembly 112 from a connection portion with the impedance adjusting mechanism 53 and is connected to the second impedance adjusting electrode 51 near the extraction electrode 34a. The other end of the impedance adjusting mechanism 53 is electrically connected to the outside of the electrostatic chuck 1111 and grounded. As illustrated in FIG. 5, unevenness in the etching rate of the substrate W occurs in the 9 o'clock to 12 o'clock direction in a plan view in which the impedance adjusting mechanism 53 and the conductive bar 54 are located.

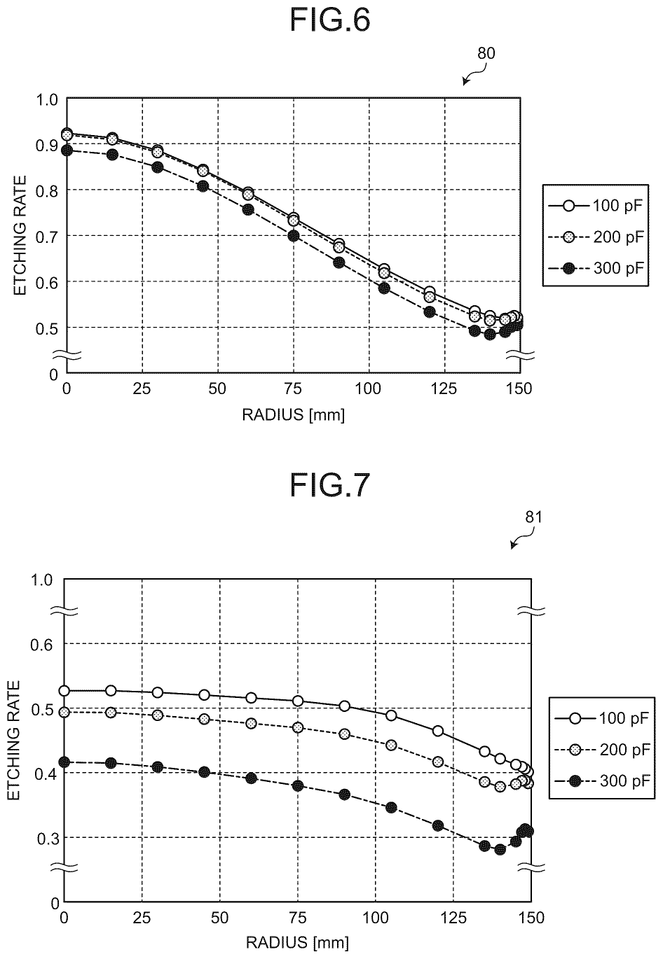

FIG. 6 and FIG. 7 are diagrams illustrating an example of change in etching rate when the impedance adjusting mechanism on the annular region side is changed. Graph 80 in FIG. 6 represents the etching rate in the radial direction when CF4/Ar gas is used as a processing gas for the etching process and the variable capacitor in the impedance adjusting mechanism 53 has values of 100 pF, 200 pF, and 300 pF. Graph 81 in FIG. 7 represents the etching rate in the radial direction when Ar/N2/C4F8 gas is used as a processing gas for the etching process and the variable capacitor in the impedance adjusting mechanism 53 has values of 100 pF, 200 pF, and 300 pF. In Graphs 80 and 81, the etching rate is normalized in a predetermined range. In the following description, the variable capacitor may also be denoted as VC (variable capacitor).

As illustrated in Graphs 80 and 81, when the value of the variable capacitor in the impedance adjusting mechanism 53 is changed from 100 pF to 200 pF and 300 pF, the etching rate changes not only on the outer peripheral side (edge side) of the substrate W but also on the central side (center side) at the same time. In other words, when the value of the variable capacitor in the impedance adjusting mechanism 53 is changed, the etching rate is shifted on the whole.

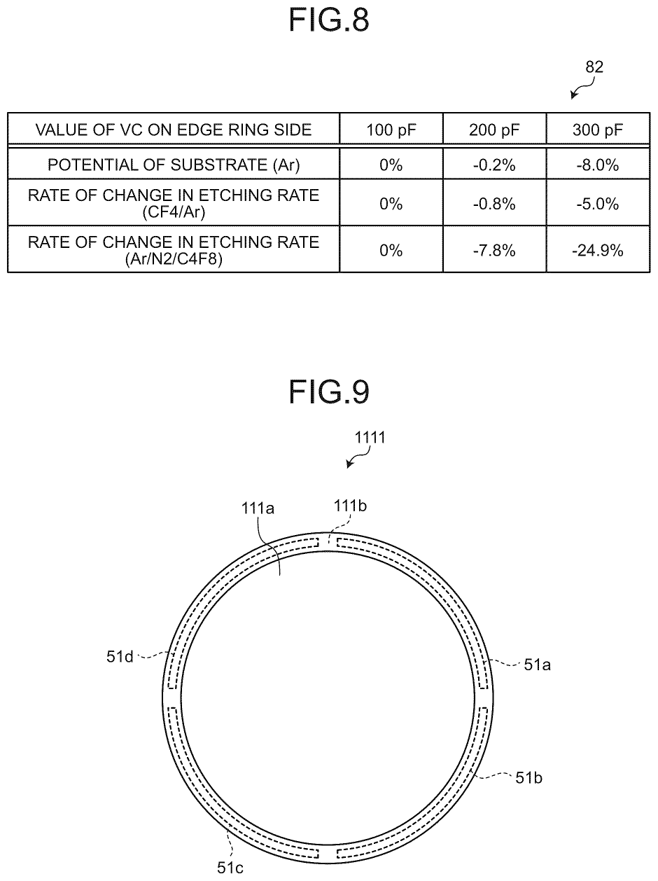

FIG. 8 is a diagram illustrating an example of the rate of change in etching rate when the impedance adjusting mechanism on the annular region side is changed. Table 82 in FIG. 8 lists the rate of change in etching rate with respect to the value of VC of the impedance adjusting mechanism 53 (represented as the value of VC on the edge ring side in FIG. 8). In Table 82, the etching rate near the center of the substrate W when the value of VC is 100 pF is used as a reference (the rate of change 0%). In a case where plasma is generated using Ar gas as a processing gas, the rate of change in potential of the substrate W is −0.2% when the value of VC is 200 pF and −8.0% when the value of VC is 300 pF. In a case where CF4/Ar gas is used as a processing gas, the rate of change in etching rate is −0.8% when the value VC is 200 pF and −5.0% when the value of VC is 300 pF. In a case where Ar/N2/C4F8 gas is used as a processing gas, the rate of change in etching rate is −7.8% when the value VC is 200 pF and −24.9% when the value of VC is 300 pF. Assuming that the allowable values for the potential of the substrate W and the rate of change in etching rate are, for example, ±3%, the rate of change in etching rate exceeds the allowable value when the value of VC is 200 pF in the case where Ar/N2/C4F8 gas is used as a processing gas. When the value of VC is 300 pF, the potential of the substrate W, the rate of change in etching rate in the case where CF4/Ar gas is used, and the rate of change in etching rate in the case where Ar/N2/C4F8 gas is used exceed the allowable values. In the first embodiment, therefore, for example, the second impedance adjusting electrode 51 is divided into a plurality of second impedance adjusting electrodes 51 in the circumferential direction of the substrate support 11, and the impedance adjusting mechanism 53 is connected to each of the second impedance adjusting electrodes 51.

Arrangement of Impedance Adjusting Electrode Referring now to FIG. 9, the arrangement of the second impedance adjusting electrode 51 will be described. FIG. 9 is a diagram illustrating an example of impedance adjusting electrodes according to the first embodiment. As illustrated in FIG. 9, the electrostatic chuck 1111 has a plurality of second impedance adjusting electrodes 51a to 51d disposed as the second impedance adjusting electrode 51 in the lower portion of the ring support surface (annular region) 111b. The second impedance adjusting electrodes 51a to 51d are connected to the respective impedance adjusting mechanisms 53. In other words, the electrostatic chuck 1111 can adjust the impedance for each of the second impedance adjusting electrodes 51a to 51d. Although not illustrated in FIG. 9, the first impedance adjusting electrode 50 is disposed in the lower portion of the substrate support surface 111a and is connected to the impedance adjusting mechanism 52.

For example, when unevenness in etching rate as illustrated in FIG. 5 occurs, the impedance adjusting mechanism 53 connected to the second impedance adjusting electrode 51d is adjusted individually. This can suppress the unevenness in etching rate with respect to the regions where the second impedance adjusting electrodes 51a are 51c are disposed. Furthermore, the electrostatic chuck 1111 can adjust the impedance adjusting mechanism 52 and the respective impedance adjusting mechanisms 53 connected to the second impedance adjusting electrodes 51a to 51d. This can suppress change (shift) in etching rate in the entire substrate W as illustrated in Graphs 80 and 81 and Table 82.

### EXPERIMENTAL RESULTS

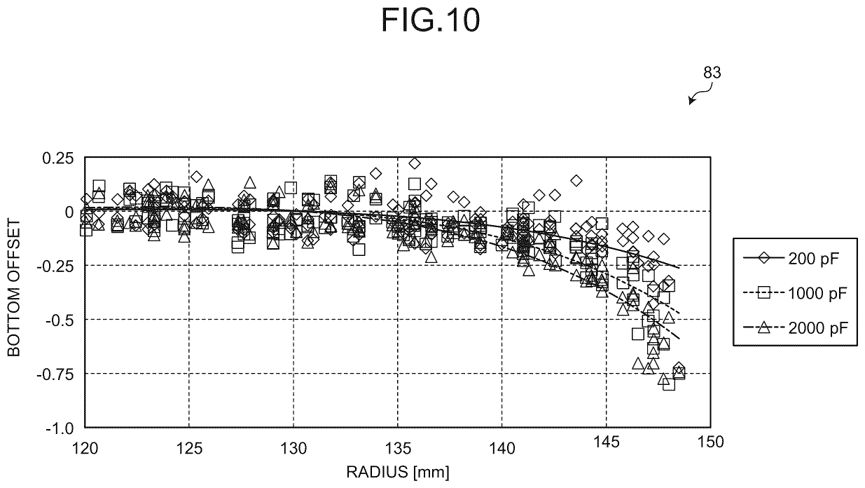

Referring now to FIG. 10, experimental results of tilt control will be described. FIG. 10 is a diagram illustrating an example of experimental results of tilt control. Graph 83 illustrated in FIG. 10 depicts measurements of bottom offset in optical critical dimension (OCD) for holes formed in a radius range of 120 mm to 150 mm for the radial direction of the substrate W. The example in Graph 83 represents the bottom offset when the values of VC of the impedance adjusting mechanism 53 are 200 pF, 1000 pF, and 2000 pF. As illustrated in Graph 83, changing the value of VC in the impedance adjusting mechanism 53 causes the bottom offset to swing to the negative side on the outer peripheral side of the substrate W (in the radius range of 130 mm to 150 mm). In other words, it can be understood that adjusting the impedance of the impedance adjusting mechanism 53 can change the potential on the ring assembly 112 side and enables the tilt control of the substrate W. Furthermore, as illustrated in FIG. 9, since the respective impedance adjusting mechanisms 53 are connected to a plurality of second impedance adjusting electrodes 51a to 51d, unevenness in etching rate can be corrected along with the tilt control.

### First Alternative Example

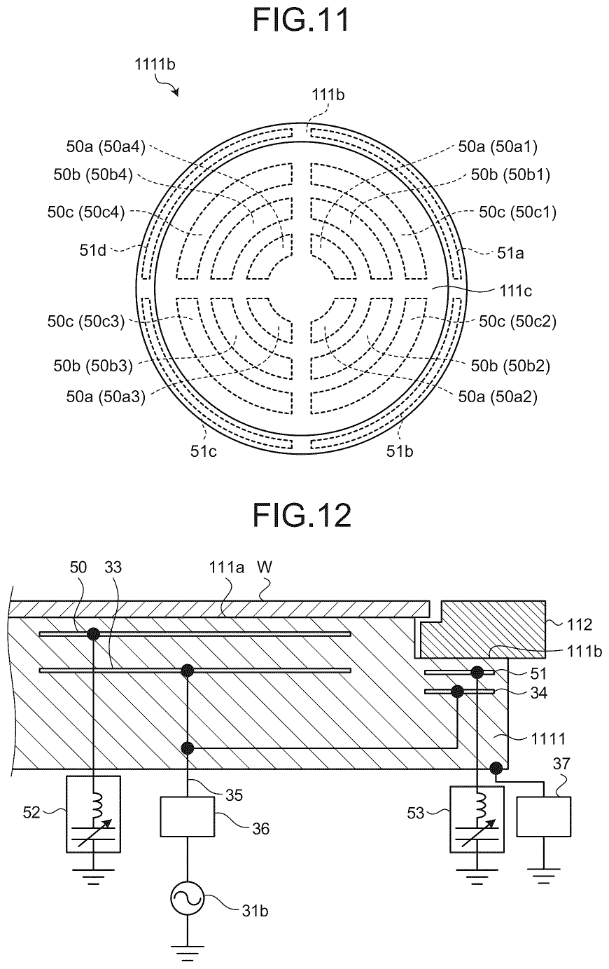

Referring now to FIG. 11, a first alternative example will be described. FIG. 11 is a diagram illustrating an example of impedance adjusting electrodes in the first alternative example. The plasma processing apparatus 1 in the first alternative example has an electrostatic chuck 1111b illustrated in FIG. 11 instead of the electrostatic chuck 1111. The plasma processing apparatus 1 in the first alternative example is similar to that of the first embodiment described above, except for the configuration of the electrostatic chuck 1111b, so the overlapping configuration and operation will not be further elaborated.

As illustrated in FIG. 11, the electrostatic chuck 1111b has a plurality of second impedance adjusting electrodes 51a to 51d disposed as the second impedance adjusting electrode 51 in the lower portion of the ring support surface (annular region) 111b, in the same manner as the electrostatic chuck 1111. The second impedance adjusting electrodes 51a to 51d are connected to the respective impedance adjusting mechanisms 53. The electrostatic chuck 1111b has a plurality of first impedance adjusting electrodes 50a to 50c as the first impedance adjusting electrode 50 in the lower portion of the substrate support surface 111c. The first impedance adjusting electrodes 50a to 50c are an example of the first impedance adjusting electrode 50 divided in the radial direction of the electrostatic chuck 1111b.

The first impedance adjusting electrodes 50a to 50c are further divided in the circumferential direction of the electrostatic chuck 1111b. In the 12 o'clock to 3 o'clock direction in a plan view of the electrostatic chuck 1111b, the first impedance adjusting electrodes 50a1, 50b1, and 50cl are disposed in order from the inside. In the 3 o'clock to 6 o'clock direction in a plan view of the electrostatic chuck 1111b, the first impedance adjusting electrodes 50a2, 50b2, and 50c2 are disposed in order from the inside. In the 6 o'clock to 9 o'clock direction in a plan view of the electrostatic chuck 1111b, the first impedance adjusting electrodes 50a3, 50b3, and 50c3 are disposed in order from the inside. In the 9 o'clock to 12 o'clock direction in a plan view of the electrostatic chuck 1111b, the first impedance adjusting electrodes 50a4, 50b4, and 50c4 are disposed in order from the inside. The first impedance adjusting electrodes 50al to 50a4, 50b1 to 50b4, and 50cl to 50c4 are connected to respective impedance adjusting mechanisms 52.

In the electrostatic chuck 1111b, when unevenness in etching rate occurs, the respective impedance adjusting mechanisms 53 connected to the second impedance adjusting electrodes 51a to 51d are adjusted individually. Furthermore, in the electrostatic chuck 1111b, the respective impedance adjusting mechanisms 52 connected to the first impedance adjusting electrodes 50al to 50a4, 50b1 to 50b4, and 50cl to 50c4 are adjusted individually. Thus, the potential can be controlled for each of the regions corresponding to the first impedance adjusting electrodes 50al to 50a4, 50b1 to 50b4, and 50cl to 50c4, and the second impedance adjusting electrodes 51a to 51d. In other words, in the first alternative example, change in etching rate can be suppressed in the entire substrate W.

In the embodiment described above, the case where the bias RF signal is supplied from the second RF generator 31b as an electrical bias has been described. However, the embodiment is not limited thereto. For example, a bias DC signal may be supplied from the bias DC generator 32a as an electrical bias. In this case, for example, the electrical path 35 includes a first electrical path that connects the second RF generator 31b, which is a first bias power supply, to at least one of the first bias electrode 33 and the second bias electrode 34. Furthermore, for example, the electrical path 35 includes a second electrical path that connects the bias DC generator 32a, which is a second bias power supply, to at least one of the first bias electrode 33 and the second bias electrode 34. Thus, the bias RF signal and the bias DC signal as desired can be supplied to the first bias electrode 33 and the second bias electrode 34.

### Second Embodiment

In the foregoing first embodiment, change in etching rate is suppressed by adjusting the impedance adjusting mechanisms 52 and 53. However, the power of an electrical bias output from the second RF generator 31b and/or the bias DC generator 32a may be controlled. An embodiment in this case will be described as a second embodiment. In the second embodiment, the same configuration as that of the plasma processing apparatus 1 of the first embodiment will be denoted by the same reference sign, and the overlapping configuration and operation will not be further elaborated.

FIG. 12 is a diagram illustrating an example of a configuration of an electrical path in the second embodiment. As illustrated in FIG. 12, in the plasma processing apparatus 1 of the second embodiment, a measurement unit 36 is provided between the second RF generator 31b and the pedestal 1110 in the electrical path 35. In the plasma processing apparatus 1 of the second embodiment, a high voltage probe 37 may be provided between the pedestal 1110 and the ground (earth, ground).

The measurement unit 36 is, for example, a VI probe and is controlled to measure the voltage and the current of a bias RF signal and/or a bias DC signal output from the second RF generator 31b and/or the bias DC generator 32a. In other words, the measurement unit 36 is controlled to measure the power of a bias RF signal and/or a bias DC signal. The measurement unit 36 outputs the measured voltage and current to the controller 2. In other words, the measurement unit 36 is configured to measure the voltage and the current of a bias RF signal and/or a bias DC signal output from the bias power supply.

The high voltage probe 37 is controlled to measure the potential (Vpp) of the pedestal 1110. For example, the high voltage probe 37 may be removed during process execution by measuring in advance the relation between the voltage of the bias RF signal measured by the measurement unit 36 and the potential (Vpp) of the pedestal 1110 measured by the high voltage probe 37. In this case, the controller 2 can estimate the potential (Vpp) of the pedestal 1110 based on the relation between the voltage of the bias RF signal measured in advance by the measurement unit 36 and the potential (Vpp) of the pedestal 1110 measured in advance.

### Control of Bias RF Power

In the second embodiment, the controller 2 controls the second RF generator 31b based on the voltage and the current input from the measurement unit 36 when at least one impedance adjusting mechanism 53 is adjusted. In other words, the second RF generator 31b has the power of the bias RF signal controlled (feedback control) so that the potential of the first bias electrode 33 and the second bias electrode 34 becomes a preset set value, based on the voltage and the current measured by the measurement unit 36. Here, the preset set value is, for example, a value with which the potential (Vpp) of the pedestal 1110 measured by the high voltage probe 37 attains a desired potential. In the second embodiment, the potential of the first bias electrode 33 and the second bias electrode 34 is described as approximately equal to the potential (Vpp) of the pedestal 1110 and the potential (Vdc) of the substrate W and the ring assembly 112.

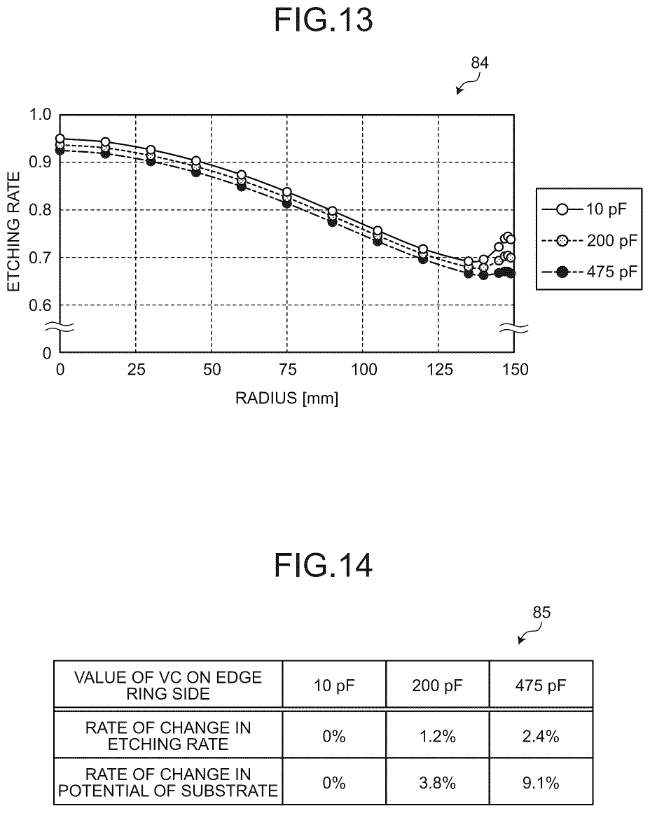

FIG. 13 is a diagram illustrating an example of change in etching rate when feedback control of bias RF power is not performed. FIG. 14 is a diagram illustrating an example of change in etching rate and in potential of a substrate when feedback control of bias RF power is not performed. Graph 84 in FIG. 13 represents the etching rate in the radial direction when Ar/N2/C4F8 gas is used as a processing gas for the etching process and the variable capacitor (VC) of the impedance adjusting mechanism 53 has values of 10 pF, 200 pF, and 475 pF. In Graph 84 and Table 85 in FIG. 14, the frequency and the power of the bias RF signal are 400 kHz and 100 W, respectively. In Graph 84, the etching rate is normalized in a predetermined range.

In Graph 84 and Table 85, the case where the variable capacitor (VC) of the impedance adjusting mechanism 53 has a value of 10 pF is the reference (the rate of change 0%). As illustrated in Graph 84 and Table 85, when feedback control of bias RF power is not performed, the rate of change in etching rate is 1.2% when the value of VC is 200 pF and 2.4% when the value of VC is 475 pF in the radius range of 0 mm to 135 mm. The rate of change in potential (Vdc) of the substrate W is 3.8% when the value of VC is 200 pF and 9.1% when the value of VC is 475 pF in the radius range of 0 mm to 135 mm.

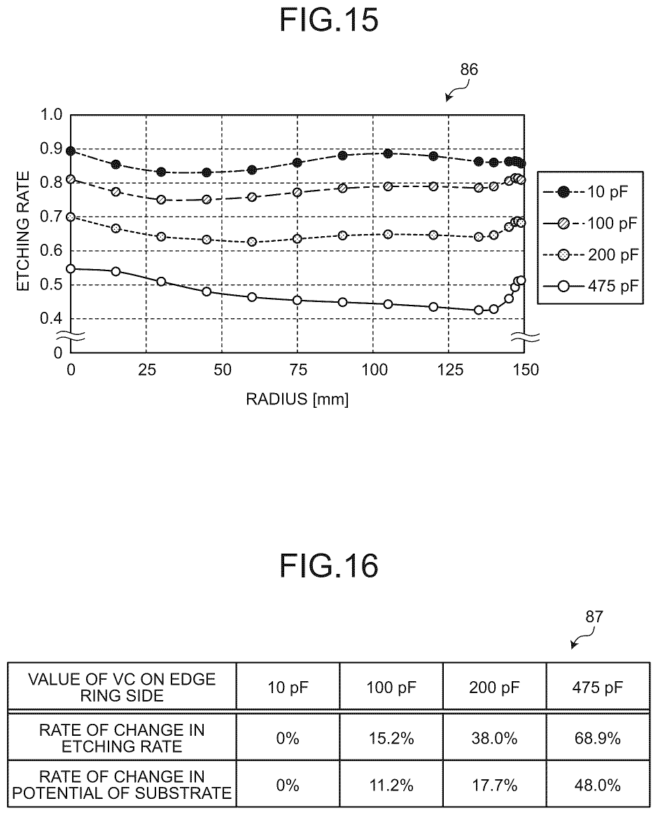

FIG. 15 is a diagram illustrating an example of change in etching rate when feedback control of bias RF power is not performed. FIG. 16 is a diagram illustrating an example of change in etching rate and in potential of a substrate when feedback control of bias RF power is not performed. Graph 86 in FIG. 15 represents the etching rate in the radial direction when Ar/N2/C4F8 gas is used as a processing gas for the etching process and the variable capacitor (VC) of the impedance adjusting mechanism 53 has values of 10 pF, 100 pF, 200 pF, and 475 pF. In Graph 86 and Table 87 in FIG. 16, the frequency and the power of the bias RF signal are 13 MHz and 300 W, respectively. In Graph 86, the etching rate is normalized in a predetermined range.

In Graph 86 and Table 87, the case where the variable capacitor (VC) of the impedance adjusting mechanism 53 has a value of 10 pF is the reference (the rate of change 0%). As illustrated in Graph 86 and Table 87, when feedback control of bias RF power is not performed, the rate of change in etching rate is 15.2% when the value of VC is 100 pF, 38.0% when the value of VC is 200 pF, and 38.9% when the value of VC is 475 pF in the radius range of 0 mm to 135 mm. The rate of change in potential (Vdc) of the substrate W is 11.2% when the value of VC is 100 pF, 17.7% when the value of VC is 200 pF, and 48.0% when the value of VC is 475 pF in the radius range of 0 mm to 135 mm. When the frequency of the bias RF signal is 13 MHz, the rate of change is greater than when the frequency is 400 kHz in both of the rate of change in etching rate and the rate of change in potential (Vdc) of the substrate W. Assuming that the allowable value of the rate of change in etching rate is, for example, ±3%, the rate of change in etching rate exceeds the allowable value when the frequency of the bias RF signal is 13 MHz and the values of VC are 100 pF, 200 pF, and 475 pF.

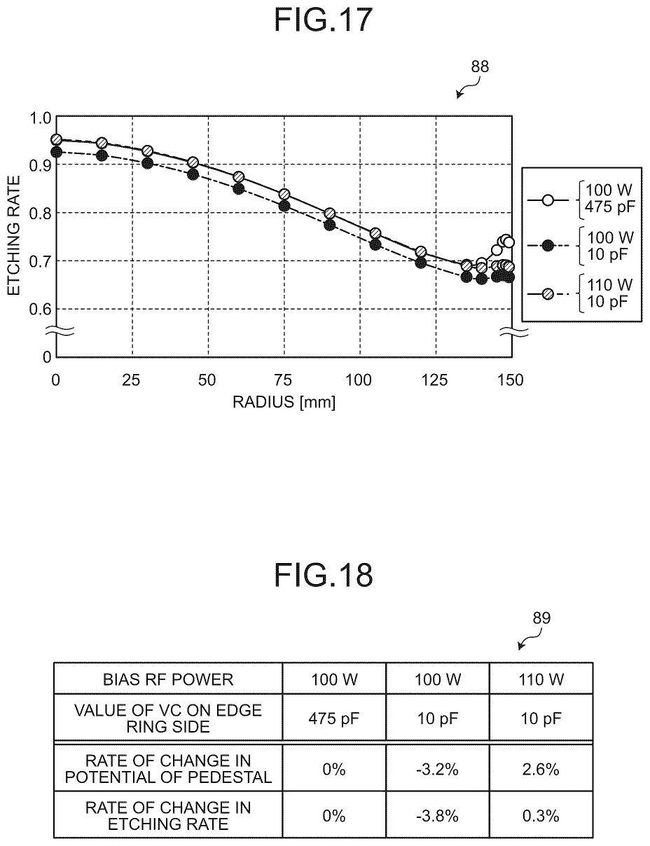

Referring now to FIG. 17 to FIG. 20, a case where feedback control of bias RF power is performed based on the potential of the first bias electrode 33 and the second bias electrode 34 (potential (Vpp) of the pedestal 1110) will be described. In other words, the controller 2 controls the second RF generator 31b to control the power of the bias RF signal so that the potential of the first bias electrode 33 and the second bias electrode 34 becomes a preset set value based on the voltage and the current input from the measurement unit 36.

FIG. 17 is a diagram illustrating an example of change in etching rate when feedback control of bias RF power is performed. FIG. 18 is a diagram illustrating an example of change in etching rate and in potential of a pedestal when feedback control of bias RF power is performed. Graph 88 in FIG. 17 represents the etching rate in the radial direction when Ar/N2/C4F8 gas is used as a processing gas for the etching process and a combination of the bias RF power and the value of VC of the impedance adjusting mechanism 53 is set as follows. In Graph 88 and Table 89 in FIG. 18, the frequency of the bias RF signal is 400 kHz. In Graph 88, the etching rate is normalized in a predetermined range.

In Graph 88 and Table 89, the case where the bias RF power is 100 W and the value of VC is 475 pF is the reference (the rate of change 0%). The potential (Vpp) of the pedestal 1110 at this time (potential of the first bias electrode 33 and the second bias electrode 34) is a set value. Graph 88 and Table 89 illustrate the etching rate in the radial direction and the rates of change in potential of the pedestal and in etching rate when the bias RF power is 100 W and the value of VC is 10 pF, and when the bias RF power is 110 W and the value of VC is 10 pF. In the combination of a bias RF power of 110 W and a VC value of 10 pF, the bias RF power is controlled from 100 W to 110 W so that the potential (Vpp) of the pedestal 1110 becomes the preset set value.

As illustrated in Graph 88 and Table 89, the potential (Vpp) of the pedestal 1110 has a rate of change of −3.2% in the combination of 100 W and 10 pF. In the combination of 110 W and 10 pF when feedback control of the bias RF power is performed, the potential (Vpp) of the pedestal 1110 has a rate of change of 2.6%. Furthermore, in the combination of 100 W and 10 pF, the etching rate has a rate of change of −3.8% in the radius range of 0 mm to 135 mm. In the combination of 110 W and 10 pF, the etching rate has a rate of change of 0.3% in the radius range of 0 mm to 135 mm. In other words, when the frequency of the bias RF signal is 400 kHz, the rate of change in etching rate meets the allowable value in the combination of 110 W and 10 pF in which feedback control of the bias RF power is performed.

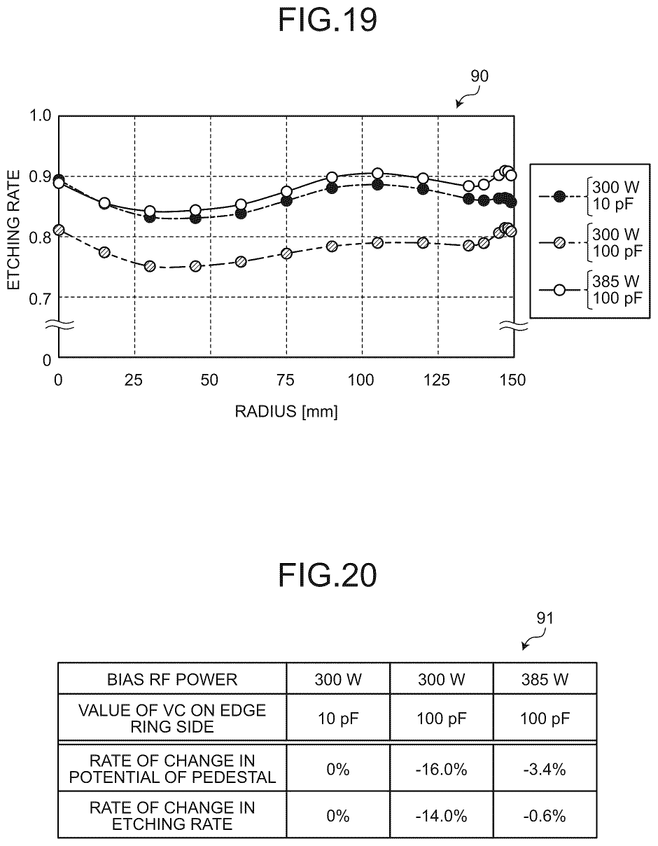

FIG. 19 is a diagram illustrating an example of change in etching rate when feedback control of bias RF power is performed. FIG. 20 is a diagram illustrating an example of change in etching rate and in potential of a pedestal when feedback control of bias RF power is performed. Graph 90 in FIG. 19 represents the etching rate in the radial direction when Ar/N2/C4F8 gas is used as a processing gas for the etching process and a combination of the bias RF power and the value of VC of the impedance adjusting mechanism 53 is set as follows. In Graph 90 and Table 91 in FIG. 20, the frequency of the bias RF signal is 12.88 MHz. In Graph 90, the etching rate is normalized in a predetermined range.

In Graph 90 and Table 91, the case where the bias RF power is 300 W and the value of VC is 10 pF is the reference (the rate of change 0%). The potential (Vpp) of the pedestal 1110 at this time (potential of the first bias electrode 33 and the second bias electrode 34) is a set value. Graph 90 and Table 91 illustrate the etching rate in the radial direction and the rates of change in potential of the pedestal and in etching rate when the bias RF power is 300 W and the value of VC is 100 pF, and when the bias RF power is 385 W and the value of VC is 100 pF. In the combination of a bias RF power of 385 W and a VC value of 100 pF, the bias RF power is controlled from 300 W to 385 W so that the potential (Vpp) of the pedestal 1110 becomes the preset set value.

As illustrated in Graph 90 and Table 91, the potential (Vpp) of the pedestal 1110 has a rate of change of −16.0% in the combination of 300 W and 100 pF. In the combination of 385 W and 100 pF when feedback control of the bias RF power is performed, the potential (Vpp) of the pedestal 1110 has a rate of change of −3.4%. Furthermore, in the combination of 300 W and 100 pF, the etching rate has a rate of change of −14.0% in the radius range of 0 mm to 135 mm. In the combination of 385 W and 100 pF, the etching rate has a rate of change of −0.6% in the radius range of 0 mm to 135 mm. In other words, when the frequency of the bias RF signal is 12.88 MHz, the rate of change in etching rate meets the allowable value in the combination of 385 W and 100 pF in which feedback control of the bias RF power is performed. In this way, in the second embodiment, the change in etching rate when the value of VC is changed can be suppressed by controlling the bias RF power.

### Control of Bias DC Power

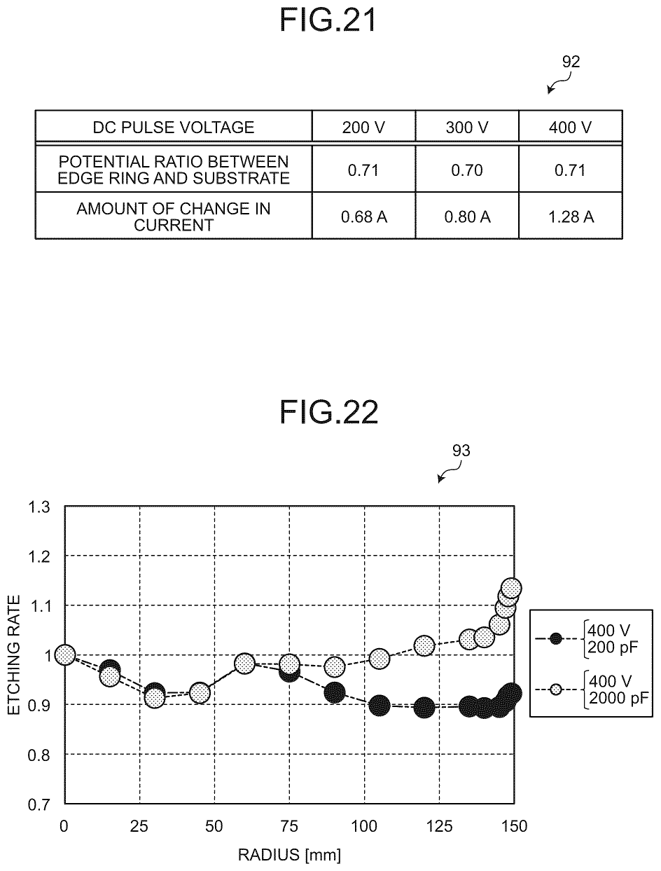

Control of the power of a bias DC signal output from the bias DC generator 32a in the second embodiment will now be described using FIG. 21 to FIG. 23. In control of the power of the bias DC signal, the second RF generator 31b in FIG. 12 reads as the bias DC generator 32a, and its configuration will not be further elaborated.

In controlling the power of the bias DC signal, the controller 2 controls the bias DC generator 32a based on the voltage and the current input from the measurement unit 36 when at least one impedance adjusting mechanism 53 is adjusted. In other words, the bias DC generator 32a has the power of the bias DC signal controlled (feedback control) so that power supplied to the first bias electrode 33 and the second bias electrode 34 becomes a preset set value, based on the voltage and the current measured by the measurement unit 36. Here, the preset set value is, for example, a value with which the potential (Vpp) of the pedestal 1110 measured by the high voltage probe 37 attains a desired potential. In determining the set value, a high voltage probe may be connected to the substrate W and the ring assembly 112 instead of the high voltage probe 37.

FIG. 21 is a diagram illustrating an example of change in current when feedback control of bias DC power is not performed. In Table 92 in FIG. 21, the source RF power is 300 W, the bias RF power is 0 W, the bias DC signal voltage (DC pulse voltage) is 200 V, 300 V and 400 V, and the value of VC of the impedance adjusting mechanism 53 is changed from 200 pF to 2000 pF. The bias DC signal has a cycle of 400 kHz and a duty ratio of 20% in a sequence of voltage pulses. Table 92 also lists the potential ratio between the ring assembly 112 (edge ring) and the substrate W, and the amount of change in current (ΔI) of the bias DC signal, in this case for each DC pulse voltage.

As indicated in Table 92, the potential ratio between the ring assembly 112 and the substrate W remains almost unchanged: 0.71 when the DC pulse voltage is 200 V, 0.70 when it is 300 V, and 0.71 when it is 400 V. On the other hand, the amount of change in current (ΔI) of the bias DC signal increases with voltage: 0.68 A when the DC pulse voltage is 200 V, 0.80 A when it is 300 V, and 1.28 A when it is 400 V. In other words, the amount of change in bias DC power when the value of VC is changed from 200 pF to 2000 pF is 136 W at 200 V, 240 W at 300 V, and 512 W at 400 V. In other words, presumably, at a high DC pulse voltage, when the value of VC of the impedance adjusting mechanism 53 is changed from 200 pF to 2000 pF, the potential (Vdc) of the substrate W fluctuates, then the current of the bias DC signal also fluctuates, and the bias DC power also fluctuates. It should be noted that when the value of VC of the impedance adjusting mechanism 53 is changed, the DC pulse voltages are each under constant voltage control.

FIG. 22 is a diagram illustrating an example of change in etching rate when feedback control of bias DC power is not performed. Graph 93 in FIG. 22 illustrates the etching rate in the radial direction when the source RF power is 300 W, the bias RF power is 0 W, the DC pulse voltage is 400 V, and the value of VC of the impedance adjusting mechanism 53 is 200 pF and 2000 pF. In Graph 93, Ar/N2/C4F8 gas is used as a processing gas for the etching process, and the etching rate is normalized in a predetermined range, where the value at the center of the substrate W (0 mm in the radial direction) is 1.

In Graph 93, the case where the variable capacitor (VC) of the impedance adjusting mechanism 53 has a value of 200 pF is the reference (the rate of change 0%). In Graph 93, the DC pulse voltage is controlled to be constant at 400 V when the value of VC is changed from 200 pF to 2000 pF. At this time, the rate of change in etching rate at a VC value of 2000 pF is 12.9% at maximum in the radius range of 0 mm to 120 mm. The rate of change in bias DC power at a VC value of 2000 pF is 91.5%. In other words, Table 92 and Graph 93 indicate that when the value of VC is changed from 200 pF to 2000 pF, the potential (Vdc) of the substrate W fluctuates and thus the etching rate also fluctuates. Assuming that the allowable value for the rate of change in etching rate is, for example, ±10%, the rate of change in etching rate exceeds the allowable value when the value of VC is 2000 pF.

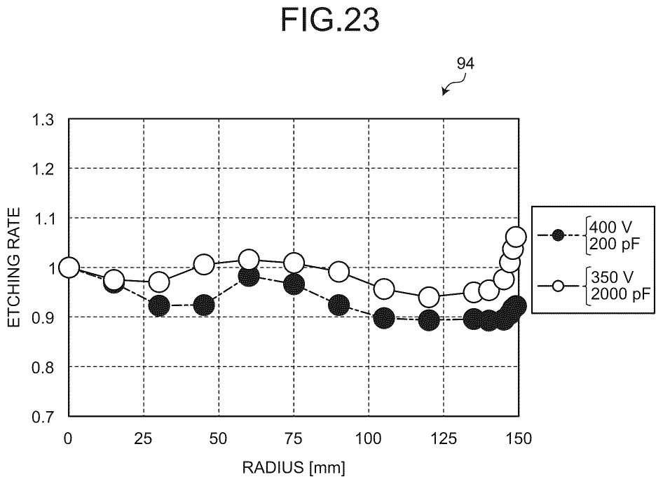

FIG. 23 is a diagram illustrating an example of change in etching rate when feedback control of bias DC power is performed. Graph 94 in FIG. 23 illustrates the etching rate in the radial direction when the source RF power is 300 W, the bias RF power is 0 W, and the value of VC of the impedance adjusting mechanism 53 is 200 pF and 2000 pF. When the value of VC is 200 pF, the DC pulse voltage is set to 400 V. On the other hand, when the value of VC is 2000 pF, the bias DC power is controlled to be constant and the DC pulse voltage is 350 V. Furthermore, in Graph 94, Ar/N2/C4F8 gas is used as a processing gas for the etching process, and the etching rate is normalized in a predetermined range, where the value at the center of the substrate W (0 mm in the radial direction) is 1.

In Graph 94, the case where the variable capacitor (VC) of the impedance adjusting mechanism 53 has a value of 200 pF is the reference (the rate of change 0%). In Graph 94, the bias DC power is controlled to be constant when the value of VC is changed from 200 pF to 2000 pF. At this time, the rate of change in etching rate at a VC value of 2000 pF is 6.7% at maximum in the radius range of 0 mm to 120 mm. The rate of change in bias DC power at a VC value of 2000 pF is 26.4%. In other words, since the bias DC power is controlled, the rate of change in etching rate meets the allowable value when the value of VC is 2000 pF. In this way, in the second embodiment, the change in etching rate when the value of VC is changed can be suppressed by controlling the bias DC power.

According to the first embodiment described above, the plasma processing apparatus 1 includes a chamber (plasma processing chamber 10), a bias power supply (second RF generator 31b), a substrate support (substrate support 11) configured to support a substrate W and an edge ring (ring assembly 112) in the chamber, a plurality of first impedance adjusting mechanisms (impedance adjusting mechanism 52), and an electrical path 35. The substrate support includes a first region (central region 111a) configured to support the substrate W, a second region (annular region 111b) provided around the first region and configured to support the edge ring, a first bias electrode 33 provided in the first region, a plurality of first impedance adjusting electrodes 50 provided in the first region and grounded, a second bias electrode 34 provided in the second region, and at least one second impedance adjusting electrode 51 provided in the second region and grounded. The plurality of first impedance adjusting mechanisms are configured to be respectively connected to the plurality of first impedance adjusting electrodes 50. The electrical path 35 is configured to connect the bias power supply, the first bias electrode 33, and the second bias electrode 34. As a result, unevenness in etching rate can be suppressed.

Furthermore, according to the first embodiment, the plasma processing apparatus further includes a second impedance adjusting mechanism (impedance adjusting mechanism 53) and a second impedance adjusting electrode 51. The second impedance adjusting mechanism is connected to the second impedance adjusting electrode 51. As a result, unevenness in etching rate can be suppressed.

Furthermore, according to the first embodiment, the plurality of first impedance adjusting electrodes 50 includes two or more first impedance adjusting electrodes 50 provided in the circumferential direction of the substrate support. As a result, the potential of the central region 111a can be adjusted for each of the circumferential regions, so that unevenness in etching rate can be suppressed. Furthermore, when there is a change (shift) in etching rate on the central side of the substrate W, the etching rate on the central side of the substrate W can be adjusted.

Furthermore, according to the first embodiment, the plurality of first impedance adjusting electrodes 50 includes two or more first impedance adjusting electrodes 50 provided in the radial direction of the substrate support. As a result, the potential of the central region 111a can be adjusted for each of the radial regions, so that unevenness in etching rate can be suppressed. Furthermore, when there is a change (shift) in etching rate on the central side of the substrate W, the etching rate on the central side of the substrate W can be adjusted.

Furthermore, according to the first embodiment, the plurality of first impedance adjusting electrodes 50 includes two or more first impedance adjusting electrodes 50 provided in each of the circumferential direction and the radial direction of the substrate support. As a result, the potential of the central region 111a can be adjusted for each of the circumferential and radial regions, so that unevenness in etching rate can be suppressed. Furthermore, when there is a change (shift) in etching rate on the central side of the substrate W, the etching rate on the central side of the substrate W can be adjusted.

Furthermore, according to the first embodiment, a plurality of the second impedance adjusting electrodes 51 and a plurality of the second impedance adjusting mechanisms are provided. A plurality of the second impedance adjusting mechanisms are configured to be respectively connected to a plurality of the second impedance adjusting electrodes 51. As a result, the impedance at a point where unevenness in etching rate occurs on the outer peripheral side of the substrate W can be adjusted, so that unevenness in etching rate can be suppressed.

Furthermore, according to the first embodiment, the plurality of second impedance adjusting electrodes 51 includes two or more second impedance adjusting electrodes 51 provided in the circumferential direction of the substrate support. As a result, the impedance at a point where unevenness in etching rate occurs on the outer peripheral side of the substrate W can be adjusted, so that unevenness in etching rate can be suppressed.

Furthermore, according to the first embodiment, the plurality of second impedance adjusting electrodes 51 includes two or more second impedance adjusting electrodes 51 provided in the radial direction of the substrate support. As a result, the impedance at a point where unevenness in etching rate occurs on the outer peripheral side of the substrate W can be adjusted, so that unevenness in etching rate can be suppressed.

According to the second embodiment, the plasma processing apparatus 1 further includes the measurement unit 36 configured to measure the voltage and the current of a bias RF signal output from the bias power supply (second RF generator 31b). The bias power supply is configured to control the power of the bias RF signal so that the potential of the first bias electrode 33 and the second bias electrode 34 becomes a preset set value, based on the voltage and the current measured by the measurement unit 36, when at least one second impedance adjusting mechanism (impedance adjusting mechanism 53) is adjusted. As a result, the change in etching rate when the value of VC is changed can be suppressed by controlling the bias RF power.

According to the second embodiment, the plasma processing apparatus 1 further includes the measurement unit 36 configured to measure the voltage and the current of a bias DC signal output from the bias power supply (bias DC generator 32a). The bias power supply is configured to control the power of the bias DC signal so that power supplied to the first bias electrode 33 and the second bias electrode 34 becomes a preset set value, based on the voltage and the current measured by the measurement unit 36, when at least one second impedance adjusting mechanism (impedance adjusting mechanism 53) is adjusted. As a result, the change in etching rate when the value of VC is changed can be suppressed by controlling the bias DC power.

Furthermore, according to the first embodiment, the plasma processing apparatus 1 includes a chamber (plasma processing chamber 10), a bias power supply (second RF generator 31b), a substrate support (substrate support 11) configured to support a substrate W and an edge ring (ring assembly 112) in the chamber, a plurality of impedance adjusting mechanisms (impedance adjusting mechanism 53), and an electrical path 35. The substrate support includes a first region (central region 111a) configured to support the substrate W, a second region (annular region 111b) provided around the first region and configured to support the edge ring, a first bias electrode 33 provided in the first region, a second bias electrode 34 provided in the second region, and a plurality of second impedance adjusting electrodes 51 provided in the second region and grounded. The plurality of impedance adjusting mechanisms are configured to be respectively connected to the plurality of second impedance adjusting electrodes 51. The electrical path 35 is configured to connect the bias power supply, the first bias electrode 33, and the second bias electrode 34. As a result, unevenness in etching rate can be suppressed.

Furthermore, according to the first embodiment, the plasma processing apparatus further includes a first impedance adjusting mechanism and a first impedance adjusting electrode 50. The first impedance adjusting mechanism is connected to the first impedance adjusting electrode 50. The impedance adjusting mechanisms are a plurality of second impedance adjusting mechanisms. As a result, unevenness in etching rate can be suppressed.

The embodiments disclosed herein are exemplary in all respects and should not be construed as limitative. The foregoing exemplary embodiments may be omitted, substituted, or modified in various forms without departing from the scope and spirit of the appended claims.

In the embodiments described above, the plasma processing apparatus 1 that performs a process such as etching on a substrate W using inductively coupled plasma as a plasma source has been described as an example. However, the technology disclosed herein is not limited thereto. As long as the apparatus performs a process on the substrate W by using plasma, the plasma source is not limited to the inductive coupling plasma, and any plasma source such as capacitive coupling plasma, microwave plasma, or magnetron plasma can be used.

The disclosure may also be configured as follows.

(1)

A plasma processing apparatus including:
a chamber;
a bias power supply;
a substrate support configured to support a substrate and an edge ring in the chamber;
a plurality of first impedance adjusting mechanisms; and
an electrical path,
the substrate support including
   a first region configured to support the substrate,
   a second region provided around the first region and configured to support the edge ring,
   a first bias electrode provided in the first region,
   a plurality of first impedance adjusting electrodes provided in the first region and grounded, and
   a second bias electrode provided in the second region, wherein
the plurality of first impedance adjusting mechanisms are configured to be respectively connected to the plurality of first impedance adjusting electrodes, and
the electrical path is configured to connect the bias power supply, the first bias electrode, and the second bias electrode.
   (2)

The plasma processing apparatus according to the above (1), further including a second impedance adjusting mechanism and a second impedance adjusting electrode, wherein
the second impedance adjusting mechanism is connected to the second impedance adjusting electrode.
   (3)

The plasma processing apparatus according to the above (1) or (2), wherein the plurality of first impedance adjusting electrodes includes two or more first impedance adjusting electrodes provided in a circumferential direction of the substrate support.

(4)

The plasma processing apparatus according to the above (1) or (2), wherein the plurality of first impedance adjusting electrodes includes two or more first impedance adjusting electrodes provided in a radial direction of the substrate support.

(5)

The plasma processing apparatus according to the above (1) or (2), wherein the plurality of first impedance adjusting electrodes includes two or more first impedance adjusting electrodes provided in each of a circumferential direction and a radial direction of the substrate support.

(6)

The plasma processing apparatus according to the above (2), wherein
a plurality of the second impedance adjusting electrodes and a plurality of the second impedance adjusting mechanisms are provided, and
a plurality of the second impedance adjusting mechanisms are configured to be respectively connected to a plurality of the second impedance adjusting electrodes.
   (7)

The plasma processing apparatus according to the above (6), wherein the plurality of second impedance adjusting electrodes includes two or more second impedance adjusting electrodes provided in a circumferential direction of the substrate support.

(8)

The plasma processing apparatus according to the above (6) or (7), wherein the plurality of second impedance adjusting electrodes includes two or more second impedance adjusting electrodes provided in a radial direction of the substrate support.

(9)

The plasma processing apparatus according to any one of the above (2) and (6) to (8), further including a measurement unit configured to measure a voltage and a current of a bias RF signal output from the bias power supply, wherein
the bias power supply is configured to control power of the bias RF signal so that potential of the first bias electrode and the second bias electrode becomes a preset set value, based on the voltage and the current measured by the measurement unit, when at least one the second impedance adjusting mechanisms is adjusted.
   (10)

The plasma processing apparatus according to any one of the above (2) and (6) to (8), further including a measurement unit configured to measure a voltage and a current of a bias DC signal output from the bias power supply, wherein
the bias power supply is configured to control power of the bias DC signal so that power supplied to the first bias electrode and the second bias electrode becomes a preset set value, based on the voltage and the current measured by the measurement unit, when at least one the second impedance adjusting mechanism is adjusted.
   (11)

A plasma processing apparatus including:
a chamber;
a bias power supply;
a substrate support configured to support a substrate and an edge ring in the chamber;
a plurality of impedance adjusting mechanisms; and
an electrical path,
the substrate support including
   a first region configured to support the substrate,
   a second region provided around the first region and configured to support the edge ring,
   a first bias electrode provided in the first region,
   a second bias electrode provided in the second region, and
   a plurality of second impedance adjusting electrodes provided in the second region and grounded, wherein
the plurality of impedance adjusting mechanisms are configured to be respectively connected to the plurality of second impedance adjusting electrodes, and
the electrical path is configured to connect the bias power supply, the first bias electrode, and the second bias electrode.
   (12)

The plasma processing apparatus according to the above (11), further including a first impedance adjusting mechanism and a first impedance adjusting electrode, wherein
the first impedance adjusting mechanism is connected to the first impedance adjusting electrode, and
the plurality of impedance adjusting mechanisms are a plurality of second impedance adjusting mechanisms.
   (13)

The plasma processing apparatus according to the above (11) or (12), wherein the plurality of second impedance adjusting electrodes includes two or more second impedance adjusting electrodes provided in a circumferential direction of the substrate support.

(14)

The plasma processing apparatus according to the above (11) or (12), wherein the plurality of second impedance adjusting electrodes includes two or more second impedance adjusting electrodes provided in a radial direction of the substrate support.

(15)

The plasma processing apparatus according to the above (11) or (12), wherein the plurality of second impedance adjusting electrodes includes two or more second impedance adjusting electrodes provided in each of a circumferential direction and a radial direction of the substrate support.

(16)

The plasma processing apparatus according to the above (12), wherein
a plurality of the first impedance adjusting electrodes and a plurality of the first impedance adjusting mechanisms are provided, and
a plurality of the first impedance adjusting mechanisms are configured to be respectively connected to a plurality of the first impedance adjusting electrodes.
   (17)

The plasma processing apparatus according to the above (16), wherein the plurality of first impedance adjusting electrodes includes two or more first impedance adjusting electrodes provided in a circumferential direction of the substrate support.

(18)

The plasma processing apparatus according to the above (16) or (17), wherein the plurality of first impedance adjusting electrodes includes two or more first impedance adjusting electrodes provided in a radial direction of the substrate support.

(19)

The plasma processing apparatus according to any one of the above (11) to (18), further including a measurement unit configured to measure a voltage and a current of a bias RF signal output from the bias power supply, wherein
the bias power supply is configured to control power of the bias RF signal so that potential of the first bias electrode and the second bias electrode becomes a preset set value, based on the voltage and the current measured by the measurement unit, when at least one the impedance adjusting mechanism is adjusted.
   (20)

The plasma processing apparatus according to any one of the above (11) to (18), further including a measurement unit configured to measure a voltage and a current of a bias DC signal output from the bias power supply, wherein
the bias power supply is configured to control power of the bias DC signal so that power supplied to the first bias electrode and the second bias electrode becomes a preset set value, based on the voltage and the current measured by the measurement unit, when at least one the impedance adjusting mechanism is adjusted.

According to aspects of embodiments, unevenness in etching rate can be suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A plasma processing apparatus comprising:
a chamber;
a bias power supply;
a substrate support configured to support a substrate and an edge ring in the chamber;
a plurality of first impedance adjusting mechanisms; and
an electrical path,
the substrate support including
a first region configured to support the substrate,
a second region provided around the first region and configured to support the edge ring,
a first bias electrode provided in the first region,
a plurality of first impedance adjusting electrodes provided in the first region and grounded, and
a second bias electrode provided in the second region, wherein
the plurality of first impedance adjusting mechanisms are configured to be respectively connected to the plurality of first impedance adjusting electrodes, and
the electrical path is configured to connect the bias power supply, the first bias electrode, and the second bias electrode.

2. The plasma processing apparatus according to claim 1, further comprising a second impedance adjusting mechanism and a second impedance adjusting electrode, wherein
the second impedance adjusting mechanism is connected to the second impedance adjusting electrode.

3. The plasma processing apparatus according to claim 1, wherein the plurality of first impedance adjusting electrodes comprises two or more first impedance adjusting electrodes provided in a circumferential direction of the substrate support.

4. The plasma processing apparatus according to claim 1, wherein the plurality of first impedance adjusting electrodes comprises two or more first impedance adjusting electrodes provided in a radial direction of the substrate support.

5. The plasma processing apparatus according to claim 1, wherein the plurality of first impedance adjusting electrodes comprises two or more first impedance adjusting electrodes provided in each of a circumferential direction and a radial direction of the substrate support.

6. The plasma processing apparatus according to claim 2, wherein
a plurality of the second impedance adjusting electrodes and a plurality of the second impedance adjusting mechanisms are provided, and
a plurality of the second impedance adjusting mechanisms are configured to be respectively connected to a plurality of the second impedance adjusting electrodes.

7. The plasma processing apparatus according to claim 6, wherein the plurality of second impedance adjusting electrodes comprises two or more second impedance adjusting electrodes provided in a circumferential direction of the substrate support.

8. The plasma processing apparatus according to claim 6, wherein the plurality of second impedance adjusting electrodes comprises two or more second impedance adjusting electrodes provided in a radial direction of the substrate support.

9. The plasma processing apparatus according to claim 2, further comprising a measurement unit configured to measure a voltage and a current of a bias RF signal output from the bias power supply, wherein
the bias power supply is configured to control power of the bias RF signal so that potential of the first bias electrode and the second bias electrode becomes a preset set value, based on the voltage and the current measured by the measurement unit, when at least one the second impedance adjusting mechanisms is adjusted.

10. The plasma processing apparatus according to claim 2, further comprising a measurement unit configured to measure a voltage and a current of a bias DC signal output from the bias power supply, wherein
the bias power supply is configured to control power of the bias DC signal so that power supplied to the first bias electrode and the second bias electrode becomes a preset set value, based on the voltage and the current measured by the measurement unit, when at least one the second impedance adjusting mechanism is adjusted.

11. A plasma processing apparatus comprising:
a chamber;
a bias power supply;
a substrate support configured to support a substrate and an edge ring in the chamber;
a plurality of impedance adjusting mechanisms; and
an electrical path,
the substrate support including
a first region configured to support the substrate,
a second region provided around the first region and configured to support the edge ring,
a first bias electrode provided in the first region,
a second bias electrode provided in the second region, and
a plurality of second impedance adjusting electrodes provided in the second region and grounded, wherein
the plurality of impedance adjusting mechanisms are configured to be respectively connected to the plurality of second impedance adjusting electrodes, and
the electrical path is configured to connect the bias power supply, the first bias electrode, and the second bias electrode.

12. The plasma processing apparatus according to claim 11, further comprising a first impedance adjusting mechanism and a first impedance adjusting electrode, wherein
the first impedance adjusting mechanism is connected to the first impedance adjusting electrode, and
the plurality of impedance adjusting mechanisms are a plurality of second impedance adjusting mechanisms.

13. The plasma processing apparatus according to claim 11, wherein the plurality of second impedance adjusting electrodes comprises two or more second impedance adjusting electrodes provided in a circumferential direction of the substrate support.

14. The plasma processing apparatus according to claim 11, wherein the plurality of second impedance adjusting electrodes comprises two or more second impedance adjusting electrodes provided in a radial direction of the substrate support.

15. The plasma processing apparatus according to claim 11, wherein the plurality of second impedance adjusting electrodes comprises two or more second impedance adjusting electrodes provided in each of a circumferential direction and a radial direction of the substrate support.

16. The plasma processing apparatus according to claim 12, wherein
a plurality of the first impedance adjusting electrodes and a plurality of the first impedance adjusting mechanisms are provided, and
a plurality of the first impedance adjusting mechanisms are configured to be respectively connected to a plurality of the first impedance adjusting electrodes.

17. The plasma processing apparatus according to claim 16, wherein the plurality of first impedance adjusting electrodes comprises two or more first impedance adjusting electrodes provided in a circumferential direction of the substrate support.

18. The plasma processing apparatus according to claim 16, wherein the plurality of first impedance adjusting electrodes comprises two or more first impedance adjusting electrodes provided in a radial direction of the substrate support.

19. The plasma processing apparatus according to claim 11, further comprising a measurement unit configured to measure a voltage and a current of a bias RF signal output from the bias power supply, wherein
the bias power supply is configured to control power of the bias RF signal so that potential of the first bias electrode and the second bias electrode becomes a preset set value, based on the voltage and the current measured by the measurement unit, when at least one the impedance adjusting mechanism is adjusted.

20. The plasma processing apparatus according to claim 11, further comprising a measurement unit configured to measure a voltage and a current of a bias DC signal output from the bias power supply, wherein
the bias power supply is configured to control power of the bias DC signal so that power supplied to the first bias electrode and the second bias electrode becomes a preset set value, based on the voltage and the current measured by the measurement unit, when at least one the impedance adjusting mechanism is adjusted.
